(19) United States
(12) Patent Application Publication
(10) Pub. No.: US 2010/0123204 A1
(43) Pub. Date: May 20, 2010

(54) Semiconductor Device and Method for Fabricating the Same

(76) Inventor: Eun Jong Shin, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/614,026

(22) Filed: Nov. 6, 2009

(30) Foreign Application Priority Data
Nov. 18, 2008 (KR) 10-2008-0114644

(51) Int. Cl. H01L 29/78; H01L 21/336

(52) U.S. Cl. 257/408; 438/305; 257/E21.435; 257/E29.266

(57) ABSTRACT

The present disclosure relates to a semiconductor device and a method of forming the semiconductor device that includes forming a gate insulating film on a semiconductor substrate, forming a polysilicon layer containing fluorine on the gate insulating film, forming a gate pattern by patterning the gate insulating film and the polysilicon layer, forming a metal layer on the semiconductor substrate including the gate pattern, and reacting the metal layer with the patterned polysilicon layer to form an FUSI dual gate having a lower Si-rich silicide layer and an upper Ni-rich silicide layer. The present method can reliably control a work function of an FUSI dual gate formed thereby, improve a device performance and an NBTI characteristic by preventing Vfb from shifting. The present invention is generally applicable to high performance devices, as well as lower power devices and memory devices.

### CROSS REFERENCE TO RELATED APPLICATION

This application claims the benefit of Korean Patent Application No. 10-2008-0114644, filed on Nov. 18, 2008, which is hereby incorporated by reference as if fully set forth herein.

### BACKGROUND OF THE DISCLOSURE

1. Field of the Disclosure

The present invention relates to a semiconductor device and a method for fabricating the same, and more particularly, to a semiconductor device, such as a transistor having a fully silicided (FUSI) gate and a method for fabricating the same.

2. Discussion of the Related Art

A CMOS (Complementary Metal Oxide Semiconductor) device having a general FUSI gate will be reviewed with reference to the attached drawing.

FIG. 1 illustrates a section of CMOS device having a general FUSI gate, provided with a semiconductor substrate 10, source/drain regions 20, an LDD (Lightly Doped Drain) region 30, a plurality of gate insulating films 50 and 60, an Si-rich silicided polysilicon layer 70, and a metal-rich silicided polysilicon layer 80.

The use of an FUSI gate can prevent some of the disadvantages of CMOS devices having polysilicon gates. For instance, poor carrier mobility of a CMOS device caused by an increased equivalent oxide thickness (EOT) due to depletion of the polysilicon gate can be avoided by using an FUSI gate. The FUSI gate is a metal-like gate. A device having the FUSI gate has an additional advantage in that a work function of a dual gate of a gate electrode can be controlled by varying a dose of an impurity dopant, such as Ge, As, P, or B, and a silicide annealing temperature according to a desired characteristic of the device. Moreover, since the gate is formed by a silicide step, a device having an FUSI gate has an improved negative bias temperature instability (NBTI) and can avoid a gate leakage caused by metal contamination that results from a reaction of a gate dielectric and metal, which is typical of devices having metal gates.

However, a conventional device having an FUSI gate has the following disadvantages in a fabrication process.

Impurity dopants injected into the gate for controlling work function of the dual gate segregate through silicon grain boundaries due to thermal treatment in a subsequent silicide annealing step. Consequently, a metal silicide reaction of the polysilicon is interrupted by the segregated dopant ions at an interface of the FUSI gate region 70 and the gate dielectric 60, forming voids 90 as shown in FIG. 1.

As a result, the work function of the dual gate increases, capacitance is reduced, and a flat band voltage (Vfb) is shifted. Such phenomena can result from reduced carrier mobility and can cause poor device characteristics, such as NBTI degradation.

Moreover, due to the voids formed in the interface of the gate 70 and the gate insulating film 60, the device having the FUSI gate is vulnerable to a gate leakage, making the device unable to generally apply to low power consumption devices, or memory devices, such as DRAM or flash memory.

### SUMMARY OF THE DISCLOSURE

Accordingly, the present invention is directed to a semiconductor device, and a method for fabricating the same.

An object of the present invention is to provide a semiconductor device, and a method for fabricating the same, that can prevent voids from forming in an interface of a gate and a gate insulating film due to impurity segregation during an annealing step for forming an FUSI gate.

Additional advantages, objects, and features of the disclosure will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for fabricating a semiconductor device includes the steps of forming a gate insulating film on a semiconductor substrate, forming a polysilicon layer containing fluorine on the gate insulating film, forming a gate pattern by patterning the gate insulating film and the polysilicon layer, forming a metal layer on the semiconductor substrate including the gate pattern, and subjecting the metal layer to a thermal process for reacting the patterned polysilicon layer with the metal layer to form a silicide.

In another aspect, the present invention includes a semiconductor device having a gate insulating film pattern on a semiconductor substrate, a Si-rich silicide layer containing fluorine on the gate insulating film pattern, and a metal-rich silicide layer containing fluorine on the Si-rich silicide layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and constitute a part of this application, illustrate embodiment(s) of the disclosure and together with the description serve to explain the principle of the disclosure. In the drawings:

FIG. 1 is a cross-sectional illustration of a conventional CMOS device having a FUSI gate.

FIGS. 2A-2H are cross-sectional illustrations showing the steps of a method for fabricating a semiconductor device in accordance with embodiments of the present invention.

FIGS. 3A-3H are cross-sectional illustrations showing the steps of a method for forming a polysilicon layer in accordance with embodiments of the present invention.

FIG. 4 is a graph showing gate voltage vs. capacitance in a semiconductor device having a FUSI gate according to the present invention and a conventional semiconductor device having a FUSI gate.

FIG. 5 is a graph showing a gate voltage vs. a drain current in a semiconductor device having a FUSI gate according to the present invention and a conventional semiconductor device having a FUSI gate.

### DESCRIPTION OF SPECIFIC EMBODIMENTS

Reference will now be made in detail to the specific embodiments of the present invention, examples of which are illustrated in the accompanying drawings. Wherever possible, the same reference numbers will be used throughout the drawings to refer to the same or like parts.

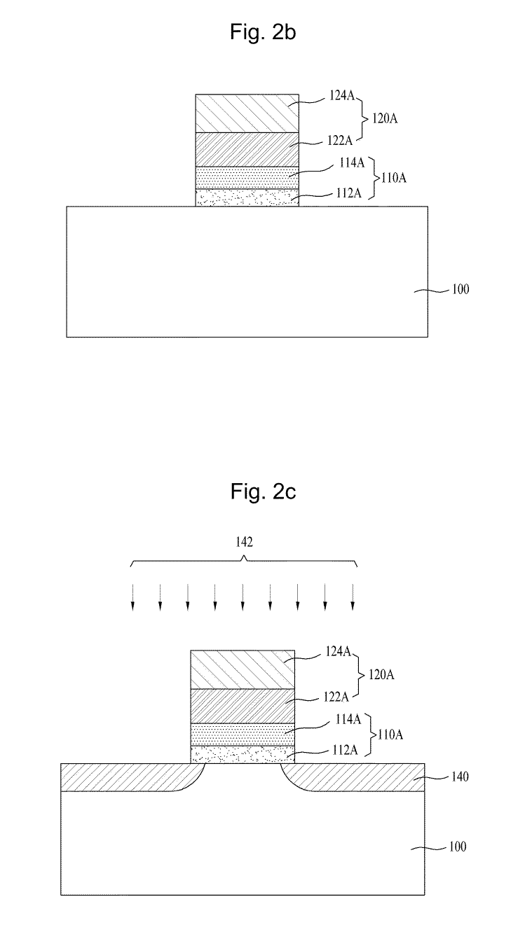

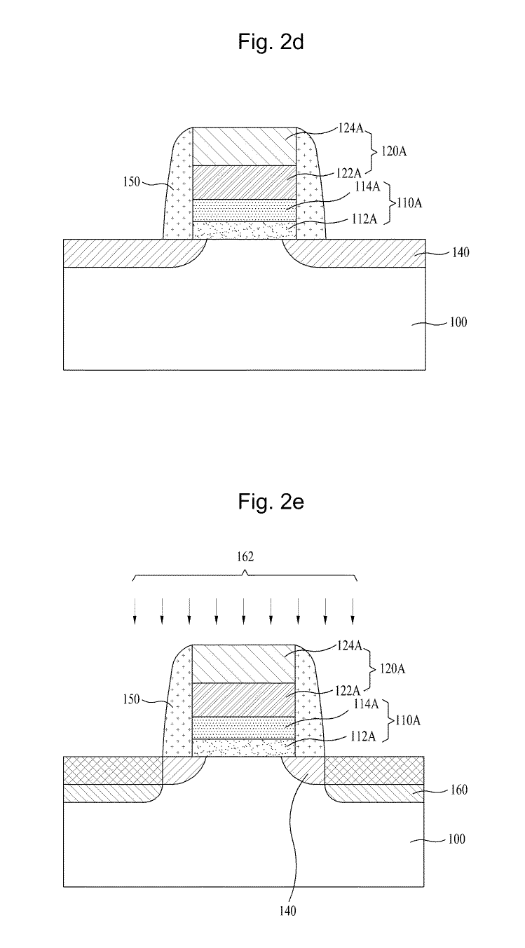

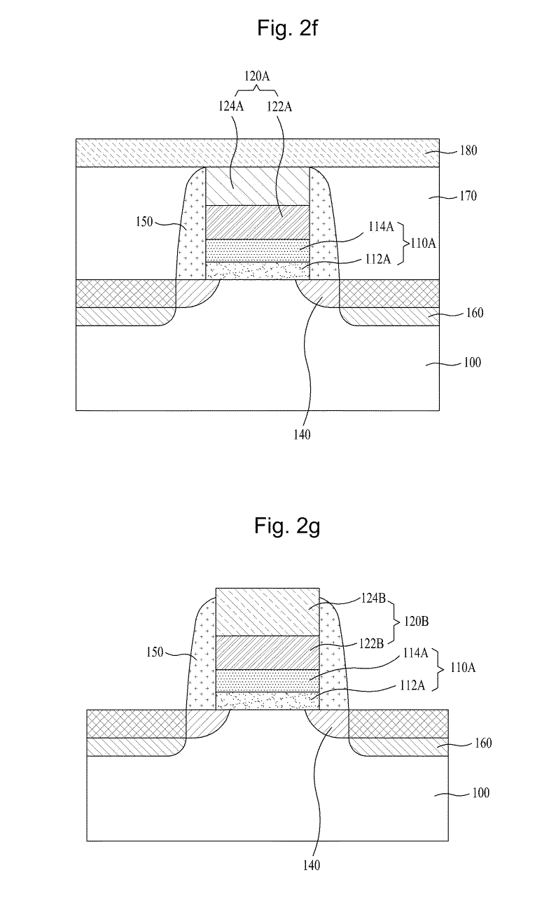

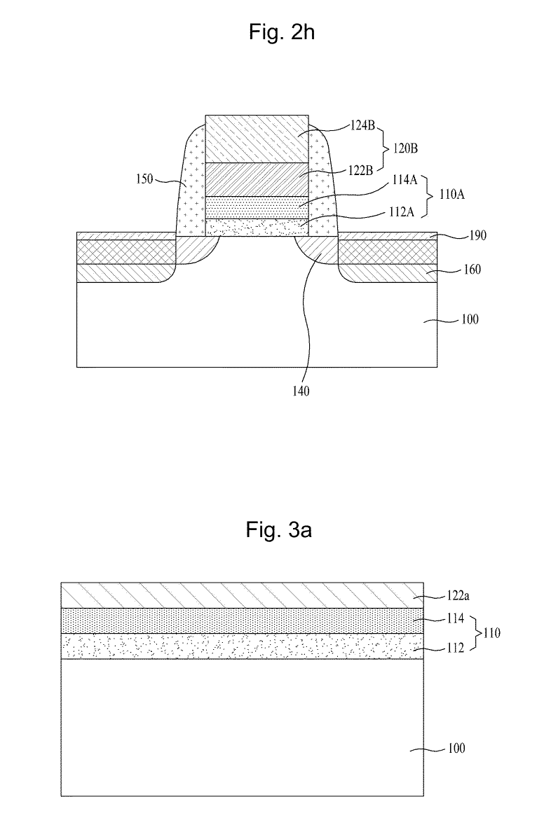

FIGS. 2A-2H illustrate sections showing the steps of a method for fabricating a semiconductor device in accordance with an exemplary embodiment of the present invention.

Referring to FIG. 2A, a gate insulating film 110 is formed on a semiconductor substrate 100. Retro-grade wells (not shown) can be formed in the semiconductor substrate 100 prior to forming the gate insulating film.

The step of forming the gate insulating film 110 can include the steps of forming a thermal oxidation film 112 and a hafnium oxide HfO₂ film 114 on the thermal oxidation film 112. In detail, the thermal oxidation film 112 is formed on the semiconductor substrate 100 by thermal oxidation (e.g., wet or dry thermal oxidation exposing the semiconductor substrate 100 to a temperature of 800 and 1200° C.). Then, the hafnium oxide film 114 is formed on the thermal oxidation film 112 by atomic layer deposition (ALD). Alternatively, the hafnium oxide film may be formed by chemical vapor deposition (e.g., plasma enhanced CVD [LPCVD] or low pressure [LPCVD]).

Then, a polysilicon layer 120 containing fluorine is formed on the gate insulating film 110. A concentration of the fluorine in an upper portion 124 of the polysilicon layer 120 can be less than a concentration of fluorine in a lower portion 122 of the polysilicon layer 120.

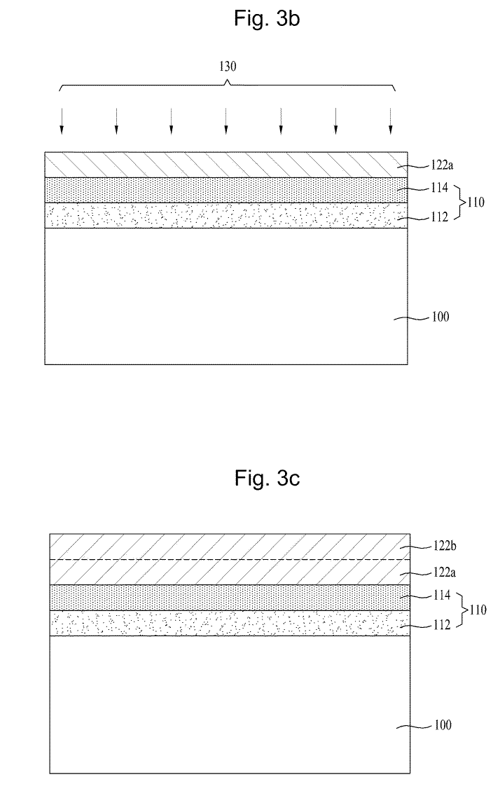

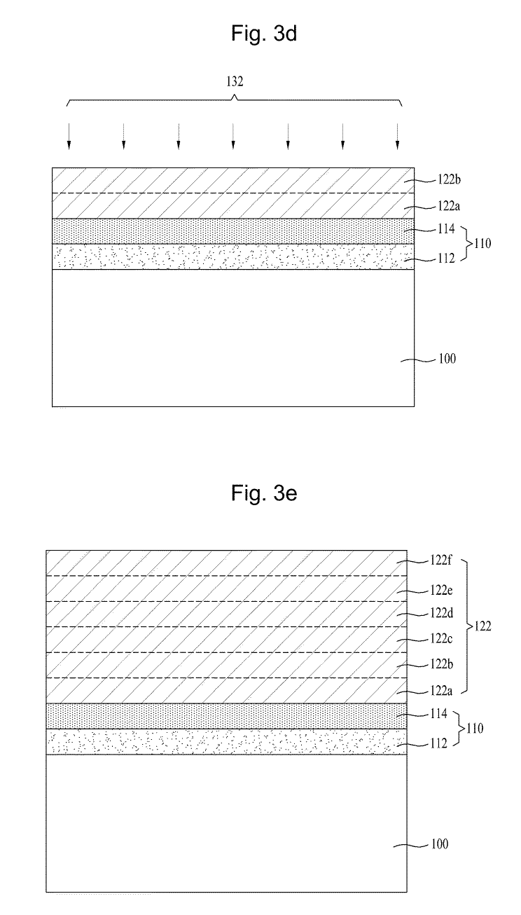

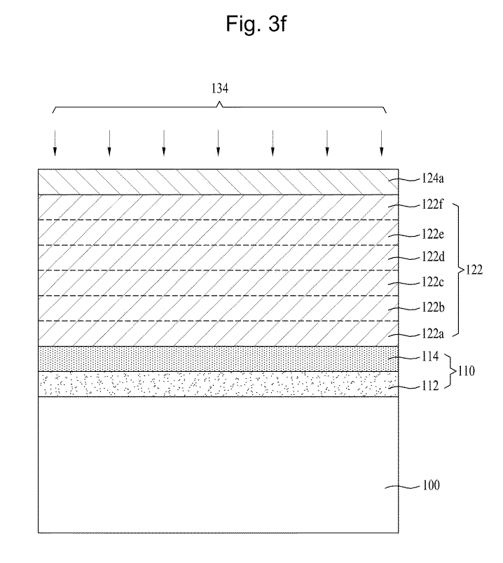

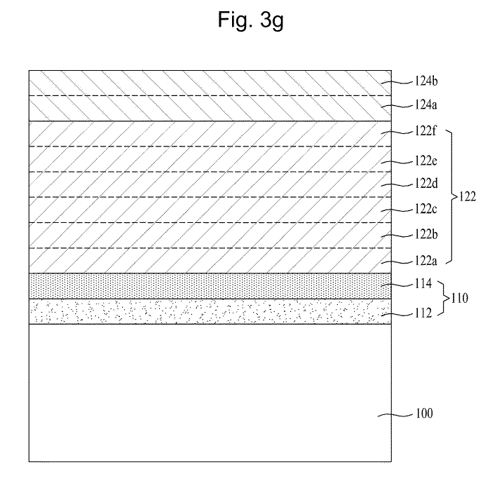

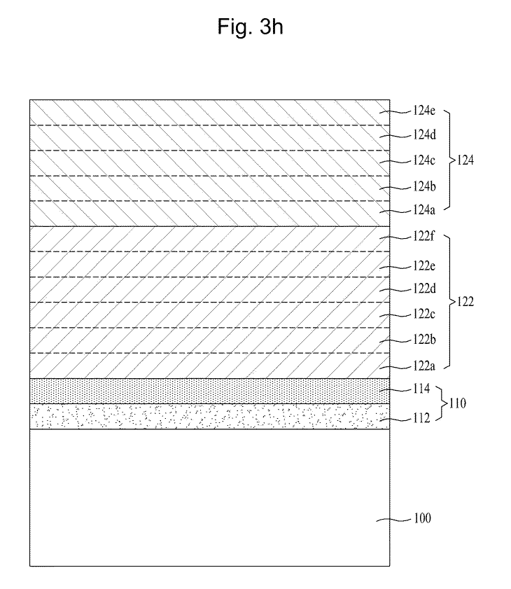

FIGS. 3A-3H illustrate sections showing the steps of a method for forming a polysilicon layer 120 (as shown in FIG. 2A) in accordance with a preferred embodiment of the present invention.

Referring to FIG. 3A, a polysilicon layer 122a is deposited on the gate insulating film 110. The polysilicon layer 122a may be blanket deposited by CVD (e.g., LPCVD, PECVD, or atmospheric pressure CVD [APCVD]). Then, as shown in FIG. 3B, fluorine ions 130 are injected into the polysilicon layer 122a throughout an entire upper surface thereof, to form a fluorinated polysilicon layer 122a as a layer within the lower portion 122 of the polysilicon 120.

Then, referring to FIG. 3C, a polysilicon layer 122b is deposited on the fluorinated polysilicon layer 122a. Polysilicon layer 122b may be formed by a same deposition process as is used to form polysilicon layer 122a. As shown in FIG. 3D, fluorine ions 132 is injected into the polysilicon throughout an entire upper surface thereof, to form a fluorinated polysilicon layer 122b. The process described above with regard to fluorinated polysilicon layers 122a and 122b can be repeated multiple times to form the lower portion 122 of the polysilicon layer 120.

For example, the process for forming the fluorinated polysilicon layers described above may be repeated six times. That is, the process used for forming fluorinated polysilicon layer 122a (e.g., the steps shown in FIGS. 3A and 3b) can be repeated six times, thereby forming six fluorinated polysilicon layers. As a result, the lower portion 122 of the polysilicon layer 120 formed on the gate insulating film 110 includes the polysilicon layers 122a-122f as shown in FIG. 3E.

Then, as shown in FIG. 3F, after depositing a polysilicon layer 124a on an entire surface of the lower portion 122 of the polysilicon layer 120, fluorine ions 134 are injected into the polysilicon layer 124a, to form a fluorinated polysilicon layer 124a as a layer within the upper portion 124 of the polysilicon layer 120. Then, as shown in FIG. 3G, the same process is repeated to form a fluorinated polysilicon layer 124b on the fluorinated polysilicon layer 124a. The process described above with regard to fluorinated polysilicon layers 124a and 124b can be repeated multiple times to form the upper portion 124 of the polysilicon layer 120.

For example, the process for forming the fluorinated polysilicon layers 124a and 124b described above may be repeated five times. That is, the process used to form fluorinated polysilicon layer 124a (e.g., the step shown in FIG. 3F) can be repeated five times, thereby forming six fluorinated polysilicon layers. As a result, the upper portion 124 of the polysilicon layer 120 may include the fluorinated polysilicon layers 124a-124e, as shown in FIG. 3H.

The polysilicon layer 120 may have a height in a range of 120 to 200 nm (e.g., 160 nm). The lower portion 122 of the polysilicon layer 120 may have a height in a range of 40 nm to 80 nm (e.g., 60 nm), and the upper portion 124 of the polysilicon layer 120 may have a height in a range of 80 nm to 120 nm (e.g., 100 nm). A thickness of each of the fluorinated polysilicon layers 122a-122f may be in a range of 6 to 14 nm (e.g., 10 nm), and a thickness of each of the fluorinated polysilicon layers 124a-124e may be in a range of 16 to 24 nm (e.g., 20 nm). As explained above, the lower portion 122 is formed by depositing polysilicon layers 122a-122f and injecting fluorine ions into each of the polysilicon layers after they are deposited. The fluorine ions can be injected into each of the polysilicon layers 122a-122f at the same ion dose of 1E15/cm². The fluorine ions can be injected into each of the polysilicon layers 122a-122f at an energy in a range of 1 to 10 KeV (e.g., 5 KeV). As explained above, the upper portion 124 is formed by depositing polysilicon layers 124a-124e and injecting fluorine ions into each of the polysilicon layers 124a-124e after they are deposited. The fluorine ions can be injected at the same ion dose of 1E15/cm², which is the same ion dose used in the formation of the fluorinated polysilicon layers 122a-122f of the lower portion 122. The fluorine ions can be injected into each of the polysilicon layers 124a-124e at an energy in a range of 1 to 15 KeV (e.g., 10 KeV). However, the invention is not limited to an ion dose of 1E15/cm². The dose of fluorine ions can be chosen from doses in the range of 5E14/cm² to 5E15 cm². Also, a lower ion dose may be chosen for injecting fluorine ions into polysilicon layers 124a-124e than is used injecting fluorine ions into polysilicon layers 122a-122f. As explained above, the polysilicon layers 122a-124e can be deposited by CVD, and are preferably formed by LPCVD.

Referring to FIG. 2B, the gate insulating film 110 and the polysilicon layer 120 are patterned, to form a gate pattern. The gate pattern includes a patterned gate insulating film 110A and a patterned polysilicon layer 120A. The gate insulating film pattern includes a thermal oxidation pattern 112A and a hafnium oxide film pattern 114A.

The gate pattern can be formed by general photolithography. That is, after coating photoresist (not shown) on the polysilicon layer 120, and exposing and developing the photoresist with a photo mask (not shown), a photoresist pattern (not shown) is formed. Then, the polysilicon layer 120 and the gate insulating film 110 are etched using the photoresist pattern as an etch mask to form gate patterns 110A (patterned gate insulating film 110A) and 120A (patterned polysilicon layer 120A) on the semiconductor substrate 100. The gate insulating film 110 and polysilicon layer 120 may be anisotropically etched with a dry etching process (e.g., reactive ion etching).

Then, referring to FIG. 2C, impurity ions 142 (p-type or n-type ions) are injected at a low dose and low energy into the semiconductor substrate 100 using the gate pattern 120A as a mask to form an Lightly Doped Drain (LDD) region 140. For example, in the case of a PMOS transistor, boron (B) ions or indium (In) ions can be lightly injected into the substrate, and in the case of an NMOS transistor, arsenic (As) ions, phosphorous (P) ions, or antimony (Sb) ions can be lightly injected into the substrate. The LDD region 140 can then be diffused to an underside of the gate patterns 110A and 120A by a thermal diffusion process.

Referring to FIG. 2D, spacers 150 are formed on sidewalls of the gate patterns 110A and 120A. After forming an insulating film (not shown) on an entire surface of the semiconductor substrate 100 including the gate patterns 110A and 120A, the insulating film can be blanket etched, to form the spacers 150. The insulating film may comprise silicon oxide or silicon nitride.

Referring to FIG. 2E, impurity ions 162 (e.g., ions of the same conductivity type as the impurity ions 142) are injected into the semiconductor substrate 100 at a high dose and a high energy using the gate patterns 120A and the spacers 150 as a mask to form source and drain regions 160. For example, in the case of a PMOS transistor, boron (B) ions or indium (In) ions can be heavily injected into the substrate, and in the case of an NMOS transistor, arsenic (As) ions, phosphorous (P) ions, or antimony (Sb) ions can be heavily injected into the substrate. The impurity ions 162 injected at the time of formation of the source and drain regions 160 are injected into the gate pattern 120A as well.

In the embodiment of the present invention, a step for forming a silicide layer on the polysilicon layer 120A and a step for forming a silicide layer on the source and drain regions 160 can be performed separately. If the step for forming a silicide layer on the polysilicon layer 120A and the step for forming a silicide layer on the source and drain regions 160 are performed at the same time, consumption of silicon in the source and drain regions 160 can become excessive, and can result in vulnerability to junction leakage.

To avoid this result, a buffer oxide film 170 is formed on an entire surface of the semiconductor substrate 100 including the gate patterns 110A and 120A. Then, the buffer oxide film is polished (e.g., by chemical mechanical polishing [CMP]) to remove and planarize the buffer oxide film 170 until an upper surface of the polysilicon layer 120A of the gate pattern is exposed, as shown in FIG. 2F. The buffer oxide film 170 can include CVD of TEOS (tetra ethyl ortho silicate), CVD using silane (e.g., SiH₄) as a silicon source and dioxygen (O₂) and/or ozone (O₃) as an oxygen source, or with spin-on-glass (SOG).

Then, a metal layer 180 is formed on the planarized buffer oxide film 170 and the exposed upper surface of the polysilicon layer 120A of the gate pattern. The metal layer 180 may comprise nickel, which may be deposited by physical vapor deposition (PVD, for example, sputtering). Alternatively, the metal layer may formed by CVD (e.g., PECVD). In an exemplary embodiment, the metal layer 180 can have a thickness of about 30 to 50 nm (e.g., 40 nm).

A resulting structure, including the metal layer 180, is subjected to thermal treatment process, to react the patterned polysilicon layer 120A with the metal layer 180 to form silicide. The thermal treatment process can comprise a Rapid Thermal Anneal (RTA, e.g., performed at 400° C. to 450° C. for 30 to 60 sec.). That is, is the metal layer 180 reacts with the upper portion 124A of the polysilicon layer 120A to from a Ni-rich silicide 124B. The lower portion 122A of the polysilicon layer 120A also reacts with the metal layer 180, but to a lesser degree, to form a Si-rich silicide 122B. The silicidation process forms a FUSI gate pattern 120B including the Ni-rich silicide 124B and the Si-rich silicide 122B. The sizes of the NiSi grains in the silicide layers 122B and 124B are different. As a result, at the time the source and drain 160 of an NMOS transistor or a PMOS transistor are formed, the segregation of fluorine and impurity dopant injected to the gate pattern 120A at the interface of the FUSI gate pattern 120B and the gate insulating film 110A through NiSi grain boundaries is prevented, thereby minimizing formation of the voids.

By adjusting a temperature of the thermal process, silicidation of the polysilicon layer 120A can be controlled. That is, by adjusting the temperature of the thermal process, a thickness of the Ni-rich silicide layer 124B and a thickness of the Si-rich silicide layer 122B can be controlled. The temperature of the thermal treatment process can be adjusted within a temperature range of 400° C.-450° C. Other parameters of the thermal treatment process may be adjusted as well, such as pressure, exposure time, etc.

Then, a portion of the metal layer 180 that is left unreacted is removed from the semiconductor substrate 100. The unreacted portion of the metal layer 180 can be removed by a blanket etch with a solution of H₂O₂ and H₂SO₄.

Then, referring to FIG. 2G, the buffer oxide film 170 is removed. For an example, the buffer oxide film 170 can be removed by a blanket etch with an HF solution.

Then, referring to FIG. 2H, after removing the buffer oxide film 170, a silicide layer 190 may be formed on the source and drain regions 160. Since processes for forming a silicide layer 190 at the source and drain regions 160 are generally known, the detailed description thereof will be omitted. For an example, for forming the silicide layer 190 at the source and drain regions 160, a thickness of the metal layer (not shown) formed on the source and drain regions 160 can be 10 to 20 nm (e.g., 15 nm). The metal layer (e.g., a Ni layer) can then be reacted with the silicon in the source and drain regions 160 in an RTA step (e.g., carrying out at a temperature of 400 to 450° C.). Any remaining unreacted metal can be removed as described above.

In an alternative embodiment of the present invention, the step for forming the silicide layers 124B and 122B and the step for forming the silicide layer 190 at the source and drain regions 160 can be performed simultaneously, as follows.

Referring to FIG. 2F, in this embodiment, no buffer oxide film 170 is formed on or over any part of the semiconductor substrate 100. Therefore, the metal layer 180 is formed on the semiconductor substrate 100 including over the gate patterns 110A and 120A and the source and drain regions 160.

Then, a thermal process is performed, to react the polysilicon layer 120A and the silicon of the source and drain regions 160 with the metal layer 180 to form silicide. As described above, the polysilicon layer 120A reacts with the metal layer to form a Ni-rich silicide layer 124B and a Si-rich silicide layer 122B. Also, a silicide layer 190 is formed on the source and drain regions 160 by the reaction of the silicon of the silicon in the source and drain region with the metal layer 180.

A semiconductor device formed by the methods described above and in accordance with a preferred embodiment of the present invention will be described below in reference to FIG. 2H.

Referring to FIG. 2H, the semiconductor device in accordance with a preferred embodiment of the present invention includes a gate insulating film pattern 110A, a silicidated polysilicon layer 120B, spacers 150, LDD regions 140, source and drain regions 160, and a silicide layer 190.

The gate insulating film pattern 110A is on the semiconductor substrate 100. In an exemplary embodiment, the gate insulating film pattern 110A can include a thermal oxidation film 112A on the semiconductor substrate 100 and a hafnium oxide film pattern 114A on the thermal oxidation film pattern 112A.

The silicidated polysilicon layer 120B can include a Si-rich silicide layer 122B and a metal-rich silicide layer 124B, both containing fluorine. The Si-rich silicide layer 122B is on the gate insulating film pattern 110A. The Si-rich silicide layer 122B is a silicidated Si-rich polysilicon layer containing fluorine. The metal-rich silicide layer 124B is on the Si-rich silicide layer 122B. The metal-rich silicide layer 124B is a silicidated metal-rich silicide layer containing fluorine. The metal can be nickel.

A concentration of the fluorine contained in the silicide layer 122B can be higher than a concentration of the fluorine contained in the metal-rich silicide layer 124B.

The LDD regions 140 are in the semiconductor substrate 100 on opposite sides of the gate insulating film pattern 110A. The spacers 150 are on sidewalls of the gate insulating film pattern 110A, and sidewall of the Si-rich silicide layer 122B and metal rich silicide layer 124B. The source and drain regions 160 are in the semiconductor substrate 100 on opposite sides of the spacers 150. The silicide layers 190 are on the source and drain regions 160.

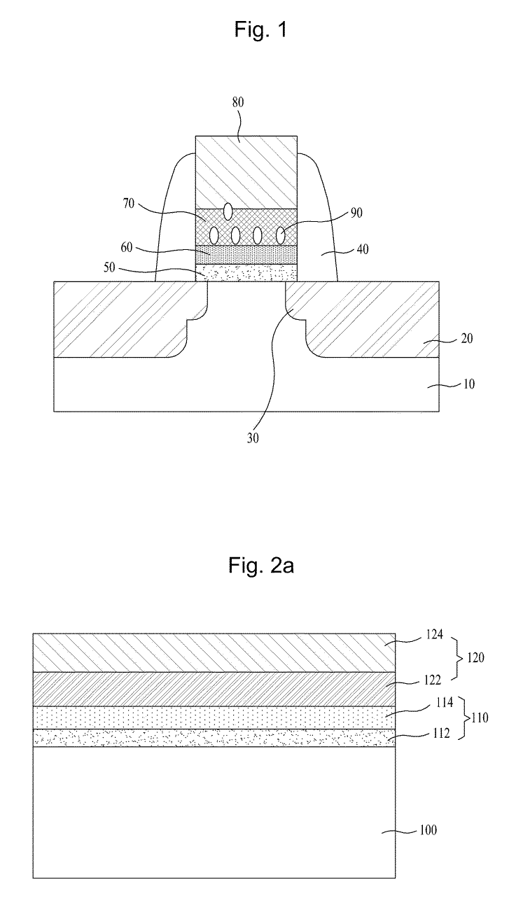

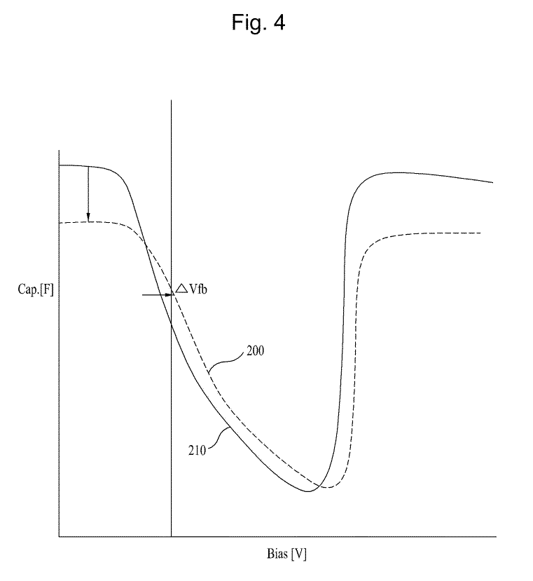

FIG. 4 is a graph showing a gate voltage vs. a capacitance in a transistor according to the present invention 210 and in a conventional device 200 (as depicted in FIG. 1), wherein a transverse axis represents a gate bias voltage and a longitudinal axis represents capacitance.

As shown in FIG. 4, since the voids 90 of the conventional device can be removed, the present invention can stabilize and control a work function of a nickel FUSI dual gate, thereby increasing the capacitance and preventing the Vfb from shifting.

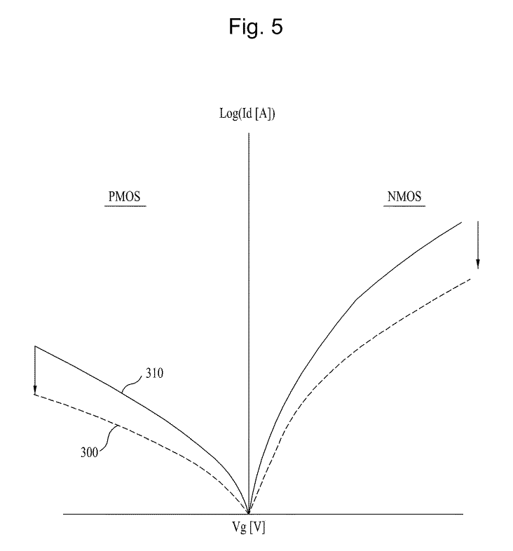

FIG. 5 illustrates a graph showing a gate voltage vs. a drain current in a transistor according to the present invention 310 and in a conventional device 300, wherein a transverse axis represents a gate voltage Vg and a longitudinal axis represents a drain current Id in a log scale [Log(Id)], and a left side represents a characteristic of a PMOS transistor, and a right side represents a characteristic of an NMOS transistor.

Referring to FIG. 5, the present invention 310 has a drain current Id greater than the drain current Id in the conventional device 300 at the same gate voltage Vg.

In conclusion, in the present invention, nickel Ni and silicon Si react to form a self-aligned NiSi silicide layer. A resulting FUSI gate pattern 120B is divided into two layers. That is, the FUSI gate pattern 120B has an FUSI structure in which the upper portion 124B of the silicide layer 120B is rich in nickel, and the lower portion 122B of the silicide layer 120B is rich in silicon. This is a result of distribution and uniformity of nickel fixed by a phase change caused by reaction of the nickel with the silicon according to the annealing temperature. Even if the present method uses a thermal budget and an annealing process similar or identical to the related art, in addition to the annealing temperature, the present invention also uses a fluorine doped polysilicon structure, including an lower polysilicon layer 122A having a higher fluorine concentration and an upper polysilicon layer 124A having a lower fluorine concentration. In contrast, conventional processes for forming FUSI gates typically use undoped polysilicon. The present invention can be effective in minimizing segregation of the impurities at or through NiSi grain boundaries at the time of a subsequent impurity ion injection.

By making a fluorine concentration of the Si-rich region 122B higher than a fluorine concentration of the Ni-rich region 124B, the size of the NiSi grains formed in the Si-rich region 122B can be smaller than the NiSi grains formed in the Ni-rich region 124B. As a result, the present invention is effective in preventing the impurity dopants from segregating during thermal exposure in a Ni silicide annealing process.

The present invention prevents voids caused by segregation of the impurities existing in an interface of the gate and the gate insulating film, which is a persistent problem of in FUSI gate devices formed by conventional techniques. Thus, the presently disclosed methods can form a nickel FUSI dual gate with favorable and stable work function, and improve an NBTI characteristic by preventing Vfb from shifting. The present methods can be used to form high performance devices, but are also generally applicable. For instance, the presently disclosed methods can be used to improve gate leakage in lower power devices, and memory devices.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a semiconductor device comprising the steps of:
forming a gate insulating film on a semiconductor substrate;
forming a polysilicon layer containing fluorine on the gate insulating film;
forming a gate pattern by patterning the gate insulating film and the polysilicon layer;
forming a metal layer on or over the semiconductor substrate including the gate pattern; and
annealing the metal layer and the patterned polysilicon layer to form a silicide.

2. The method as claimed in claim 1, wherein the metal layer comprises nickel.

3. The method as claimed in claim 1, wherein the polysilicon layer comprises an upper layer having a lower concentration of fluorine and a lower layer having a higher concentration of the fluorine.

4. The method as claimed in claim 3, wherein forming the polysilicon layer includes the steps of:
depositing a first plurality of polysilicon layers on the gate insulating film and injecting fluorine ions into the each of the first plurality of polysilicon layers to form the lower portion of the polysilicon layer, and
depositing a second plurality of polysilicon layers on the lower portion of the polysilicon layer and injecting fluorine ions into each of the second plurality of polysilicon layers to form the upper portion of the polysilicon layer.

5. The method as claimed in claim 4, wherein the first plurality of polysilicon layers comprises six polysilicon layers, and the second plurality of polysilicon layers comprises five polysilicon layers.

6. The method as claimed in claim 4, wherein an equal dose of fluorine ions is injected into each of the first plurality of polysilicon layers and each of the second plurality of polysilicon layers.

7. The method as claimed in claim 1, forming the gate insulating film includes the steps of:
forming a thermal oxidation film on the semiconductor substrate; and
forming a hafnium oxide film on the thermal oxidation film.

8. The method as claimed in claim 1, further comprising the step of forming a retro-grade well in the semiconductor substrate.

9. The method as claimed in claim 1, further comprising:
forming a buffer oxide film over an entire surface of the semiconductor substrate including the gate pattern after forming the gate pattern, and
polishing the buffer oxide film until an upper surface of the gate pattern is exposed.

10. The method as claimed in claim 9, wherein the metal layer is formed on the polished buffer oxide film and the gate pattern.

11. The method as claimed in claim 1, further comprising:
forming an LDD region by lightly injecting impurities into the semiconductor substrate using the gate pattern as a mask;
forming spacers on sidewalls of the gate pattern;
forming source and drain regions by heavily injecting impurities into the semiconductor substrate using the gate pattern and the spacers as a mask;
removing an unreacted portion of the metal layer; and
forming a source/drain silicide layer on the source and drain regions.

12. The method as claimed in claim 3, wherein an upper portion of the silicide layer comprises a metal-rich silicide and a lower portion of the silicide layer comprises a Si-rich silicide.

13. The method as claimed in claim 1, wherein the annealing is performed at a temperature effective to control a thickness of the metal-rich upper portion of the silicide layer.

14. The method as claimed in claim 11, wherein removing the unreacted portion of the metal layer comprises etching with a solution of H₂O₂ and H₂SO₄.

15. A semiconductor device comprising:
a gate insulating film pattern on a semiconductor substrate;
a Si-rich silicide layer containing fluorine on the gate insulating film pattern; and
a metal-rich silicide layer containing fluorine on the Si-rich silicide layer.

16. The semiconductor device as claimed in claim 15, wherein the gate insulating film pattern includes:
a thermal oxidation film pattern on the semiconductor substrate; and
a hafnium oxide film pattern on the thermal oxidation film pattern.

17. The semiconductor device as claimed in claim 15, wherein the metal comprises nickel.

18. The semiconductor device as claimed in claim 15, wherein the Si-rich silicide layer includes a higher concentration of fluorine than the metal-rich silicide layer.

19. The semiconductor device as claimed in claim 15, further comprising:
LDD regions in the semiconductor substrate on opposite sides of the gate insulating film pattern;
spacers on a sidewall of the gate insulating film pattern, a sidewall of the Si-rich silicide layer, and a sidewall the metal-rich silicide layer;
source and drain regions in the semiconductor substrate on opposite sides of the spacers; and
source/drain silicide layers on the source and drain regions.
